(19) United States
(12) Patent Application Publication
(10) Pub. No.: US 2025/0224679 A1
(43) Pub. Date: Jul. 10, 2025

(54) RESIST PATTERN FORMATION METHOD

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 19/092,092

(22) Filed: Mar. 27, 2025

Related U.S. Application Data
(63) Continuation-in-part of application No. PCT/JP2023/032396, filed on Sep. 5, 2023.

(30) Foreign Application Priority Data
Sep. 28, 2022 (JP) 2022-155494

(51) Int. Cl. G03F 7/16; G03F 7/004; G03F 7/09; G03F 7/11; G03F 7/32

(52) U.S. Cl. CPC G03F 7/167; G03F 7/0042; G03F 7/094; G03F 7/11; G03F 7/32

(57) ABSTRACT

A method for forming a resist pattern, includes: forming a metal-containing resist film directly or indirectly on a substrate; laminating a protective film on the metal-containing resist film by applying a composition for forming a protective film; exposing to light the metal-containing resist film on which the protective film is laminated; and removing a portion of the exposed metal-containing resist film to form a pattern.

### CROSS-REFERENCE TO RELATED APPLICATIONS

The present application is a continuation-in-part application of International Patent Application No. PCT/JP2023/032396 filed Sep. 5, 2023, which claims priority to Japanese Patent Application No. 2022-155494 filed Sep. 28, 2022. The contents of these applications are incorporated herein by reference in their entirety.

### BACKGROUND OF THE DISCLOSURE

### Technical Field

The present disclosure relates to a method for forming a resist pattern.

### Background Art

In a general method for forming a pattern to be used for microfabrication by lithography, a resist film formed of a radiation-sensitive composition for forming a resist film is exposed to an electromagnetic wave such as a far ultraviolet ray (e.g., an ArF excimer laser beam or a KrF excimer laser beam) or an extreme ultraviolet ray (EUV), a charged particle beam such as an electron beam, or the like to generate an acid in an exposed area. Then, a chemical reaction using this acid as a catalyst causes a difference in dissolution rate with respect to a developer between the exposed area and the unexposed area, with the result that a pattern is formed on a substrate. The pattern formed can be used as a mask or the like in substrate processing. Such a method for forming a pattern is required to improve resist performance along with miniaturization of processing technology. In response to this requirement, the types, molecular structures, and the like of an organic polymer, an acid generator, and other components to be used in a radiation-sensitive composition for forming a resist film have been studied, and also combinations of the types, molecular structures, and the like have been further studied in detail (see JP-A-2000-298347). It has also been studied to use a metal-containing compound instead of an organic polymer.

### SUMMARY

According to an aspect of the present disclosure, a method for forming a resist pattern, includes: forming a metal-containing resist film directly or indirectly on a substrate; laminating a protective film on the metal-containing resist film by applying a composition for forming a protective film; exposing to light the metal-containing resist film on which the protective film is laminated; and removing a portion of the exposed metal-containing resist film to form a pattern.

### BRIEF DESCRIPTION OF THE DRAWINGS

FIG. 1 is a schematic plan view of a line pattern as viewed from above; and

FIG. 2 is a schematic cross-sectional view of a line pattern shape.

### DESCRIPTION OF THE EMBODIMENTS

In the exposure using EUV, there is a disadvantage that together with EUV light having a wavelength of 13.5 nm, light having a wavelength of about 150 nm to 350 nm is emitted as out-of-band, causing deterioration in resolution, nano-edge roughness, and the like of the resist. In addition, since EUV exposure is performed under vacuum, there is a high demand for reduction of outgas generated from the resist film at the time of exposure, and in addition, it is necessary to sufficiently satisfy the sensitivity of the resist. Studies by the inventors have revealed that these problems exist not only in a resist composition in which an organic polymer is used but also in a resist composition in which a metal-containing compound is used.

The present disclosure relates to, in one embodiment, a method for forming a resist pattern, including:
forming a metal-containing resist film directly or indirectly on a substrate;
laminating a protective film on the metal-containing resist film with a composition for forming a protective film;
exposing to light the metal-containing resist film on which the protective film is laminated; and
removing a portion of the exposed metal-containing resist film to form a pattern.

According to the method for forming a resist pattern of the present disclosure, in a method for forming a pattern using a resist composition in which a metal compound is used, the nano-edge roughness can be improved, the sensitivity of the resist can be sufficiently satisfied, and also the generation of outgas from the resist film can be suppressed. Therefore, the present disclosure can be suitably used for formation of a fine resist pattern in a lithography step for various electronic devices such as semiconductor devices and liquid crystal devices.

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Hereinafter, each embodiment of the present disclosure will be described in detail.

A method for forming a resist pattern according to the present embodiment includes: forming a metal-containing resist film directly or indirectly on a substrate (hereinafter, also referred to as a “metal-containing resist film forming step”); laminating a protective film on the metal-containing resist film with a composition for forming a protective film (hereinafter, also referred to as a “protective film laminating step”); exposing to light the metal-containing resist film on which the protective film is laminated (hereinafter, also referred to as an “exposing step”); and removing a portion of the exposed metal-containing resist film to form a pattern (hereinafter, also referred to as a “pattern forming step”).

Before the metal-containing resist film forming step, forming a resist underlayer film directly or indirectly on the substrate (hereinafter, also referred to as a “resist underlayer film forming step”) may be included.

Hereinafter, each step of the method for forming a resist pattern will be described.

### [Metal-Containing Resist Film Forming Step]

In this step, a metal-containing resist film is formed directly or indirectly on a substrate.

The metal-containing resist film can be formed by depositing a metal compound on the substrate.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferable. The substrate may be a substrate on which a silicon nitride film, an alumina film, a silicon dioxide film, a tantalum nitride film, a titanium nitride film or the like is formed.

Examples of the case where the metal-containing resist film is indirectly formed on the substrate include a case where the metal-containing resist film is formed on a resist underlayer film described later formed on the substrate.

The deposition of the metal compound may be performed by vapor deposition by chemical vapor deposition (CVD) or atomic layer deposition (ALD). The vapor deposition may be performed by plasma-enhanced (PE) CVD or plasma-enhanced (PE) ALD.

The deposition temperature in ALD may be 50° C. to 600° C. The deposition pressure in ALD may be 100 to 6000 mTorr. The flow rate of the metal compound in ALD may be 0.01 to 10 ccm and the gas flow rate (CO₂, CO, Ar, N₂) may be 100 to 10000 sccm. Plasma power in ALD supplied using high-frequency plasma (for example, a frequency of 13.56 MHz, 27.1 MHz, or higher) may be 200 to 1000 W per 300 mm wafer station.

Processing conditions suitable for vapor deposition by CVD include a deposition temperature of about 250° C. to 350° C. (for example, 350° C.), a reactor pressure of less than 6 Torr (for example, maintained at 1.5 to 2.5 Torr at 350° C.), a plasma power/bias of 200 W per 300 mm wafer station supplied using high-frequency plasma (for example, 13.56 MHz or more), a metal compound flow rate of about 100 to 500 ccm, and a CO₂ flow rate of about 1000 to 2000 sccm.

Examples of the metal compound include a compound represented by formula (I):

M(X)₄ (I)

In formula (I), M is Sn or Hf. Xs are each independently a halogen atom, or a substituted or unsubstituted alkyl group, alkoxy group, or amide group.

The compound represented by formula (I) is preferably at least one selected from the group consisting of haloalkyl Sn, alkoxyalkyl Sn, and amidoalkyl Sn. Among them, preferable specific examples of the compound represented by formula (I) include tetramethyltin, tetrafluorotin, methyltris(methoxymethyl)tin, trimethyltin chloride, dimethyltin dichloride, methyltin trichloride, tris(dimethylamino)methyltin(IV), (dimethylamino)trimethyltin(IV), tetrabromotin, and tetrachlorohafnium.

The metal-containing resist film preferably contains an organotin oxide.

### [Protective Film Laminating Step]

In this step, a protective film is laminated on the metal-containing resist film with a composition for forming a protective film described later. This composition for forming a protective film is usually applied so as to cover the surface of the metal-containing resist film. By laminating the protective film on the surface of the metal-containing resist film, the influence of out-of-band generated during exposure to light can be reduced, and the nano-edge roughness in the obtained pattern can be improved. In addition, since the protective film is formed of a polymer having a high glass transition temperature, permeation of volatile components generated by the metal-containing resist film can be suppressed, and outgas can be reduced.

The coating method is not particularly limited as long as the coating method is a method in which the composition for forming a protective film is applied so as to cover the surface of the metal-containing resist film, and examples thereof include spin coating, casting coating, roll coating, and the like. The thickness of the protective film to be formed is usually 10 nm to 1,000 nm, preferably 10 nm to 500 nm.

After the composition for forming a protective film is applied, a solvent in the coating film may be volatilized by prebaking, if necessary. The prebaking temperature is appropriately selected depending on the blending composition of the composition for forming a protective film, but is usually 30° C. to 200° C., preferably 50° C. to 150° C. The duration of prebaking is usually from 5 seconds to 600 seconds, preferably from 10 seconds to 300 seconds.

The protective film formed of the composition for forming a protective film preferably absorbs light having a wavelength of 150 nm or more and 350 nm or less. As such a protective film, for example, when an optical constant (extinction coefficient) of the protective film in the wavelength range of 150 nm or more and 350 nm or less is measured using a spectroscopic ellipsometer or the like, the maximum value of the extinction coefficient in this range is preferably 0.3 or more, more preferably 0.5 or more. The maximum value of the extinction coefficient may be the maximum value of the peak or otherwise. For example, the maximum value of the peak may be outside the wavelength range, provided that the value of the extinction coefficient at the tail of the peak satisfies the above condition in the above wavelength range. When the protective film can absorb light having a wavelength of 150 nm or more and 350 nm or less, the protective film formed of the composition for forming a protective film in the method for forming a resist pattern can further reduce the influence of out-of-band that EUV light generates.

### [Exposing Step]

In this step, the metal-containing resist film on which the protective film is laminated is exposed to light. This step causes a difference in solubility in a developer between an exposed portion and an unexposed portion on the metal-containing resist film. More specifically, the solubility of the exposed portion in a developer on the metal-containing resist film is increased.

The radiation to be used for the exposure can be appropriately selected depending on the type of the metal-containing resist film to be used, and the like. Examples of the radiation include electromagnetic waves such as visible rays, ultraviolet rays, far ultraviolet rays, X-rays, and γ-rays, and particle beams such as electron beams, molecular beams, and ion beams. Among them, far ultraviolet rays are preferable, and a KrF excimer laser beam (wavelength: 248 nm), an ArF excimer laser beam (wavelength: 193 nm), an F₂ excimer laser beam (wavelength: 157 nm), a Kr₂ excimer laser beam (wavelength: 147 nm), an ArKr excimer laser beam (wavelength: 134 nm), or an extreme ultraviolet ray (wavelength: 13.5 nm, etc., also referred to as “EUV”) is more preferable, and EUV is still more preferable. In addition, exposure conditions can be appropriately determined depending on the type of the metal-containing resist film to be used, and the like.

The EUV exposure causes a dimerization reaction of an organotin oxide in the exposed portion of the metal-containing resist film. For example, CH₃Sn(SnO)₃, which is an organotin oxide, can produce Sn₂((SnO)₃)₂ by a dimerization reaction caused by the EUV exposure.

In this step, post exposure baking (hereinafter, also referred to as “PEB”) can be performed after the exposure in order to improve the resist film performance such as resolution, pattern profile, and developability. The PEB temperature and the duration of PEB can be appropriately determined depending on the type of a material for forming the metal-containing resist film to be used, and the like. The lower limit of the PEB temperature is preferably 50° C., more preferably 70° C. The upper limit of the PEB temperature is preferably 500° C., more preferably 300° C. The lower limit of the duration of PEB is preferably 10 seconds, more preferably 30 seconds. The upper limit of the duration of PEB is preferably 600 seconds, more preferably 300 seconds.

In this step, heating can be performed during exposure. The lower limit of the heating temperature is preferably 20° C., more preferably 30° C. The upper limit of the heating temperature is preferably 70° C., more preferably 60° C.

### [Pattern Forming Step]

In this step, as one embodiment, an exposed portion of the exposed metal-containing resist film is dissolved in a developer to form a positive resist pattern. The dimerized reactant of an organotin oxide in the metal-containing resist film is dissolved in the developer to develop the metal-containing resist film. Specifically, Sn₂((SnO)₃)₂ generated through the dimerization reaction by EUV exposure is dissolved in the developer, so that the metal-containing resist film is developed to form a resist pattern. The protective film can be removed by development with a known alkaline developer or development with an organic solvent.

Examples of the developer to be used in this step include water, alcohol-based liquids, and ether-based liquids, and two or more types thereof can be used in combination.

Examples of the alcohol-based liquids include monoalcohol-based liquids such as methanol, ethanol, n-propanol, iso-propanol, n-butanol, iso-butanol, sec-butanol, t-butanol, n-pentanol, iso-pentanol, sec-pentanol, t-pentanol, 2-methylpentanol, and 4-methyl-2-pentanol.

Examples of the ether-based liquids include polyhydric alcohol partial ether-based solvents such as ethylene glycol monomethyl ether, ethylene glycol monoethyl ether, ethylene glycol dimethyl ether, and propylene glycol monoethyl ether, and polyhydric alcohol partial ether acetate-based liquids such as ethylene glycol monomethyl ether acetate, ethylene glycol monoethyl ether acetate, propylene glycol monomethyl ether acetate (PGMEA), and propylene glycol monoethyl ether acetate.

As the developer, water and alcohol-based liquids are preferable, and water, ethanol, or a combination thereof is more preferable.

The temperature of the developer can be appropriately determined depending on the type of a material for forming the metal-containing resist film to be used, and the like. The lower limit of the temperature of the developer is preferably 20° C., more preferably 30° C., still more preferably 40° C. The upper limit of the temperature of the developer is preferably 70° C., more preferably 60° C. The lower limit of the duration of development is preferably 10 seconds, more preferably 30 seconds. The upper limit of the duration of development is preferably 600 seconds, more preferably 300 seconds.

In this step, the exposed portion of the exposed metal-containing resist film may be dissolved in the developer, and then washing and/or drying may be performed.

In this step, an unexposed portion of the exposed metal-containing resist film can also be removed by heating to form a negative resist pattern. In that case, a metal compound for forming the metal-containing resist film is preferably represented by formula (1).

M(X)₄ (1)
wherein in formula (1), M is Sn or Hf; and Xs are each independently a halogen atom or an alkyl group.

Among the compounds represented by formula (1), at least one selected from the group consisting of Sn(CH₃)₄, Sn(Br)₄, and HfCl₄ is preferable.

In this step, an unexposed portion of the exposed metal-containing resist film can be volatilized to form a resist pattern. The volatilization may be performed by heating as described above, may be performed by reducing the pressure, or may be performed by combining heating and pressure reduction.

Substrate etching may be performed using the resist pattern obtained in the present disclosure as a mask. The number of times of etching may be once or twice or more, that is, etching may sequentially be performed using the pattern obtained by etching as a mask. Examples of an etching method include dry etching and wet etching. As a result of the etching, a semiconductor substrate having a prescribed pattern is obtained.

### [Resist Underlayer Film Forming Step]

In this step, which may be included in the present embodiment, first, the composition for forming a resist underlayer film is applied to the substrate directly or indirectly. The method for applicating the composition for forming a resist underlayer film is not particularly limited, and the application can be performed by an appropriate method such as spin coating, cast coating, or roll coating. As a result, a coating film is formed, and a solvent in the composition for forming a resist underlayer film is volatilized or the like, whereby a resist underlayer film is formed. The composition for forming a resist underlayer film will be described later.

Next, the coating film formed by the application is heated. Heating the coating film promotes formation of the resist underlayer film. More specifically, heating the coating film promotes volatilization or the like of a solvent in the composition for forming a resist underlayer film.

The heating of the coating film may be performed either in the air atmosphere or in a nitrogen atmosphere. The lower limit of the heating temperature is preferably 100° C., more preferably 150° C., still more preferably 200° C. The upper limit of the heating temperature is preferably 400° C., more preferably 350° C., still more preferably 280° C. The lower limit of the duration of heating is preferably 15 seconds, more preferably 30 seconds. The upper limit of the duration is preferably 1,200 seconds, more preferably 600 seconds.

The lower limit of the average thickness of the resist underlayer film to be formed is preferably 0.5 nm, more preferably 1 nm, still more preferably 2 nm. The upper limit of the average thickness is preferably 50 nm, more preferably 20 nm, still more preferably 10 nm, particularly preferably 7 nm. The average thickness is measured as described in Examples.

As the composition for forming a resist underlayer film to be used in the step, for example, compositions described in WO2018/173446, WO2018/179704, and the like can be used.

### <Composition for Forming Protective Film>

The composition for forming a protective film according to the present embodiment contains a polymer [A] and an organic solvent [B]. The composition for forming a protective film may contain an optional component in addition to the polymer [A] and the organic solvent [B] as long as the effect of the present disclosure is not impaired.

In the method for forming a resist pattern, the composition for forming a protective film is used for coating the surface of a resist film and is used for forming a protective film on the resist film.

Hereinafter, each of the components will be described.

### [Polymer [A]]

The polymer [A] preferably has a structural unit (I) containing a cyclic structure. Owing to the structural unit (I), the out-of-band generated during exposure can be absorbed, and the glass transition temperature is relatively high. As a result, the protective film formed of the composition for forming a protective film can improve the nano-edge roughness of the obtained resist pattern, and can suppress outgas generated from the resist film. The polymer [A] may have a structural unit other than the structural unit (I).

Examples of the structural unit (I) include at least one selected from the group consisting of structural units represented by formulas (1) to (4), and among them, at least one selected from the group consisting of a structural unit represented by formula (1) (hereinafter, also referred to as “structural unit (I-1)”) and a structural unit represented by formula (2) (hereinafter, also referred to as “structural unit (I-2)”) is preferable.

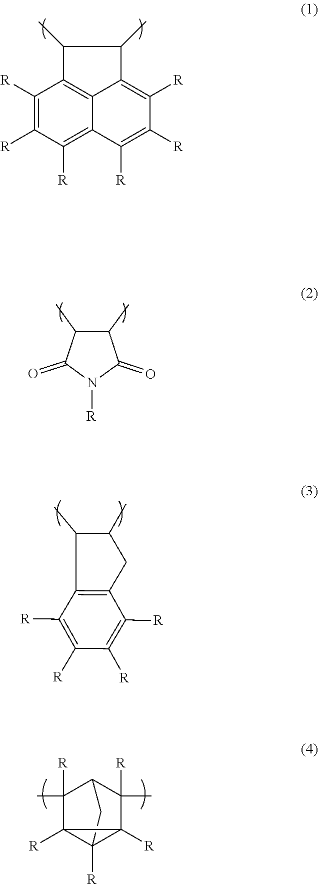

In formulas (1) to (4), Rs are each independently a hydrogen atom, a halogen atom, a hydroxy group, or a monovalent organic group having 1 to 20 carbon atoms.

Examples of the monovalent organic group having 1 to 20 carbon atoms represented by R include a monovalent hydrocarbon group having 1 to 20 carbon atoms, a monovalent organic group containing a heteroatom-containing group between carbon and carbon of the hydrocarbon group or at a terminal of the hydrocarbon group, and a group in which some or all of hydrogen atoms of the hydrocarbon group or the organic group are substituted with a substituent.

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the heteroatom include an oxygen atom, a nitrogen atom, a sulfur atom, and a phosphorus atom.

Examples of the heteroatom-containing group include —O—, —CO—, —NH—, —S—, or a group obtained by combining them.

Examples of the substituents include halogen atoms such as a fluorine atom, a chlorine atom, a bromine atom, and an iodine atom, a hydroxyl group, a carboxyl group, a cyano group, a nitro group, an alkoxy group, an alkoxycarbonyl group, and an acyl group.

Preferable examples of R include an organic group represented by —L¹-(R⁷)ₙ.

L¹ is a single bond or a (n+1)-valent group derived from a hydrocarbon having 1 to 20 carbon atoms.

Examples of the hydrocarbon having 1 to 20 carbon atoms represented by L¹ include an alkane having 1 to 5 carbon atoms, a cycloalkane having 3 to 15 carbon atoms, and an arene having 6 to 20 carbon atoms.

Examples of the (n+1)-valent group derived from an alkane having 1 to 5 carbon atoms include groups obtained by removing (n+1) hydrogen atoms from alkanes such as methane, ethane, propane, butane, and pentane.

Examples of the (n+1)-valent group derived from a cycloalkane having 3 to 15 carbon atoms include groups obtained by removing (n+1) hydrogen atoms from cycloalkanes such as cyclopropane, cyclobutane, cyclopentane, cyclohexane, cyclodecane, norbornane, and adamantane.

Examples of the (n+1)-valent group derived from an arene having 6 to 20 carbon atoms include groups obtained by removing (n+1) hydrogen atoms from arenes such as benzene, toluene, xylene, mesitylene, naphthalene, anthracene, and phenanthrene.

R⁷ is a group having at the terminal a halogen atom, a hydroxy group, or an —OR^{A} group, and a carbon atom to which the group is bonded has at least one fluorine atom or fluorinated alkyl group (hereinafter, also referred to as “group (a)”). R^{A} is a hydrogen atom or a monovalent organic group having 1 to 20 carbon atoms. As the monovalent organic group having 1 to 20 carbon atoms represented by R^{A}, the monovalent organic groups having 1 to 20 carbon atoms represented by R can be suitably employed, provided that, when L¹ is a single bond, R⁷ is a group (a).
n is 1 or 2.

### (Structural Unit (I-1))

The L¹ in the structural unit (I-1) is preferably a single bond or a methylene group, more preferably a single bond, from the viewpoint of increasing the glass transition temperature of the polymer [A].

The R⁷ is preferably the group (a). Such a group (a) is not particularly limited as long as the group (a) has this structure, but is preferably a group represented by formula (a′).

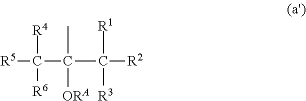

In formula (a′), R¹ to R⁶ are each independently a hydrogen atom, a halogen atom, or a perfluoroalkyl group having 1 to 5 carbon atoms, provided that at least one of R¹ to R⁶ is a fluorine atom or a perfluoroalkyl group having 1 to 5 carbon atoms. R^{A} has the same meaning as R^{A} in the R⁷.

Examples of the halogen atom represented by R¹ to R⁶ include a fluorine atom, a chlorine atom, a bromine atom, and an iodine atom.

Examples of the perfluoroalkyl group having 1 to 5 carbon atoms represented by R¹ to R⁶ include a trifluoromethyl group, a pentafluoroethyl group, a linear or branched heptafluoropropyl group, a nonafluorobutyl group, and an undecafluoropentyl group.

As the R¹ to R⁶, a fluorine atom or a perfluoroalkyl group is preferable, and a fluorine atom is more preferable.

The R^{A} is preferably a hydrogen atom from the viewpoint of further improving the development and removal properties of the protective film.

Examples of the group (a) include a methylfluoromethylhydroxymethyl group, a methyldifluoromethylhydroxymethyl group, a methyltrifluoromethylhydroxymethyl group, a di(fluoromethyl)hydroxymethyl group, a di(trifluoromethyl)hydroxymethyl group, a trifluoromethylpentafluoroethylhydroxymethyl group, and a di(pentafluoroethyl)hydroxymethyl group. Among them, a di(trifluoromethyl)hydroxymethyl group is preferable.

R is preferably a hydrogen atom from the viewpoint of further increasing the sensitivity of the resist film on which the protective film is laminated, and is also preferably a hydroxy group or a group (a) from the viewpoint of further improving the removability by development of the protective film, and is more preferably a hydrogen atom, a hydroxy group, or a di(trifluoromethyl)hydroxymethyl group.

Examples of the structural unit (I-1) include structural units represented by formulas (1-1-1) to (1-1-12) (hereinafter, also referred to as “structural units (I-1-1) to (I-1-12)”).

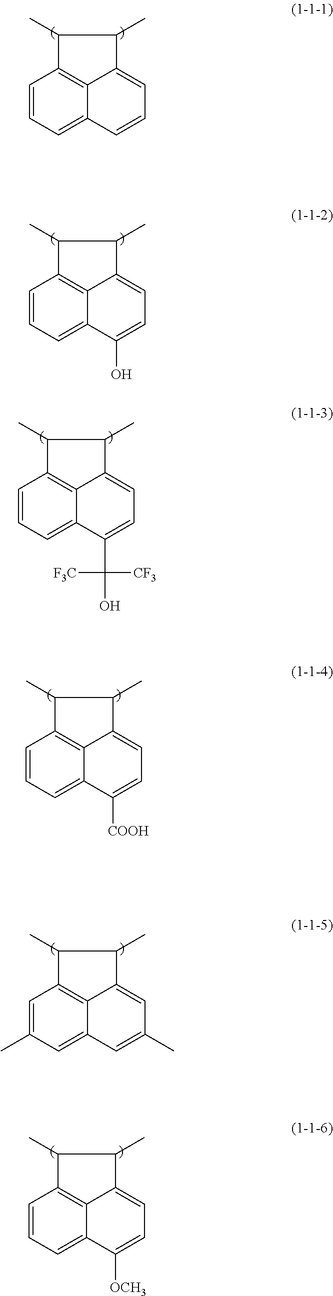

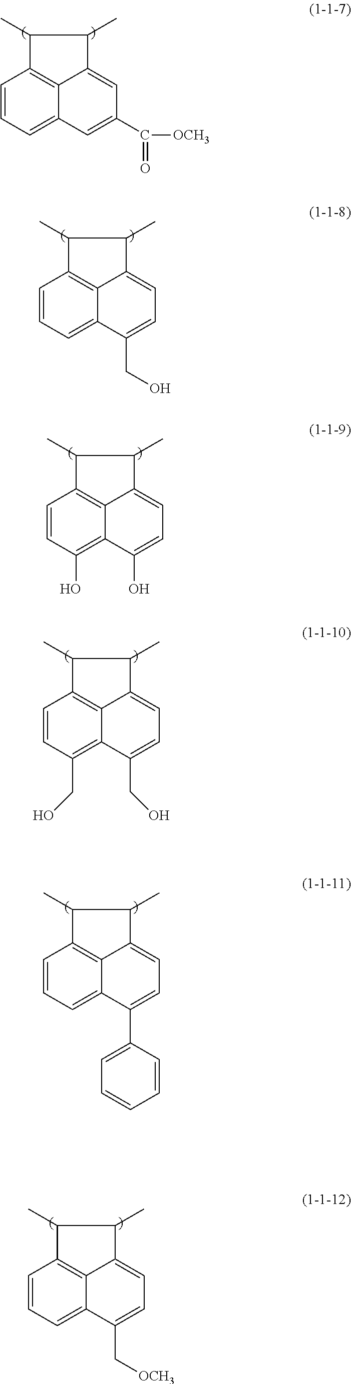

Among them, the structural units (I-1-1) to (I-1-3) are preferable.

### (Structural Unit (I-2))

As the L¹ in the structural unit (I-2), a (n+1)-valent group derived from an alkane having 1 to 5 carbon atoms, a cycloalkane having 3 to 15 carbon atoms, or an arene having 6 to 20 carbon atoms is preferable, and a divalent or trivalent group derived from methane, ethane, cyclohexane, or benzene is particularly preferable.

Examples of the structural unit (I-2) include structural units represented by formulas (1-2-1) to (1-2-8) (hereinafter, also referred to as “structural units (I-2-1) to (I-2-8)”).

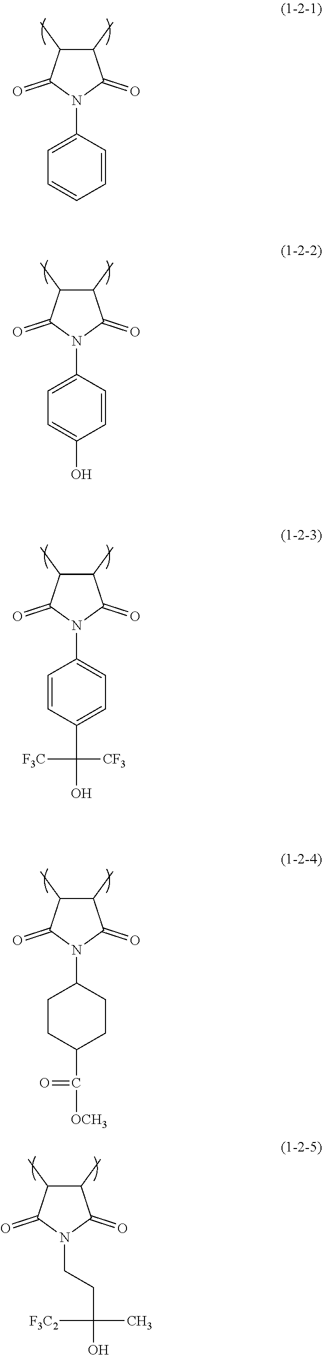

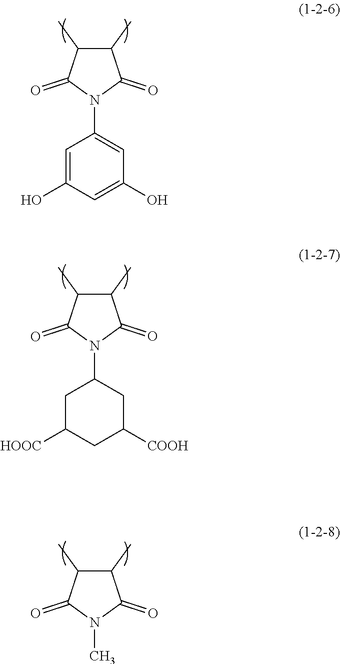

Among them, the structural units (I-2-1) and (I-2-2) are preferable.

The lower limit of the content ratio of the structural unit (I) is preferably 10 mol %, more preferably 25 mol %, still more preferably 40 mol % with respect to all structural units constituting the polymer [A].

The upper limit of the content ratio of the structural unit (I) is preferably 100 mol %, more preferably 80 mol %, still more preferably 70 mol %. By adjusting the content ratio of the structural unit (I) within the above range, the nano-edge roughness of the resist pattern obtained by the method for forming a resist pattern can be improved, and also the sensitivity and outgas suppression property can be improved.

Examples of the monomer that gives the structural unit (I) include compounds represented by formulas (1-1-1m) to (1-2-8m) (hereinafter, also referred to as “compounds (1-1-1m) to (1-2-8m)”).

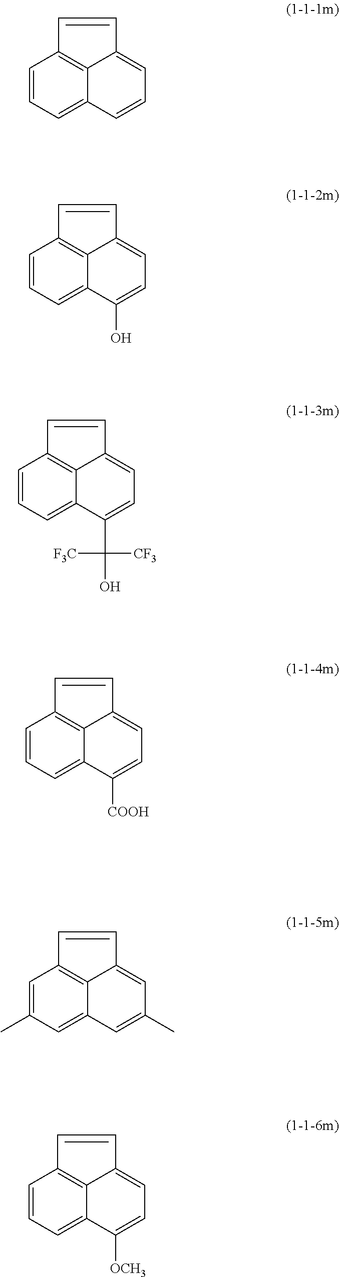

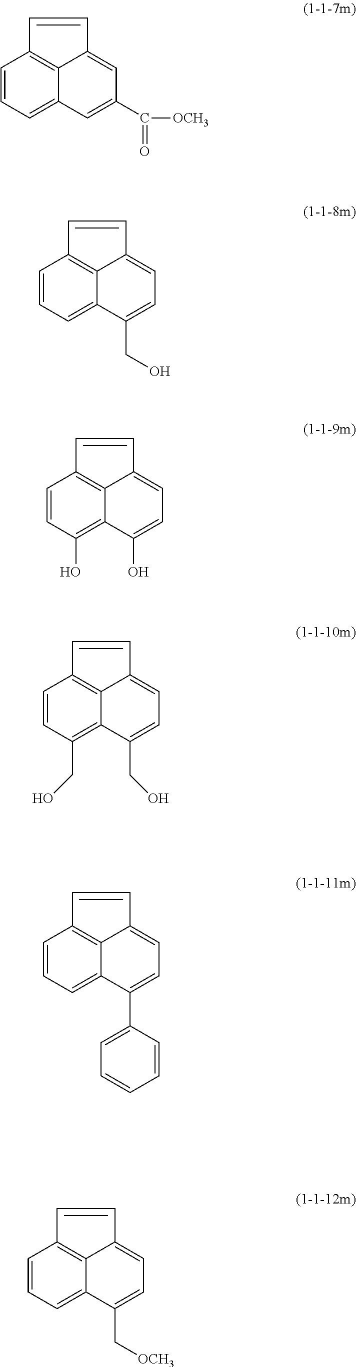

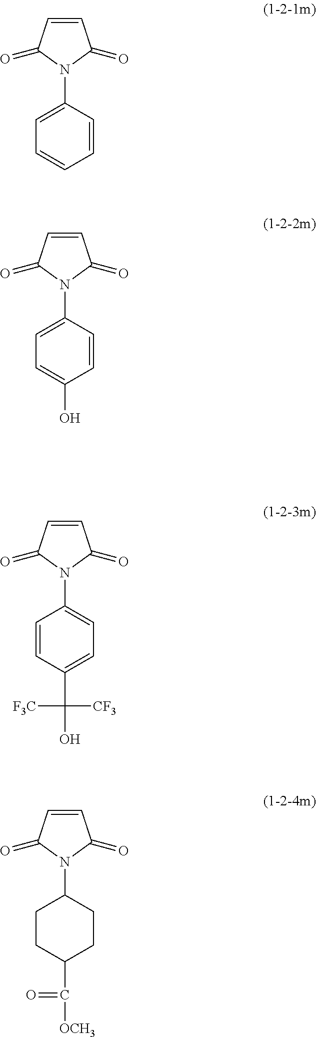

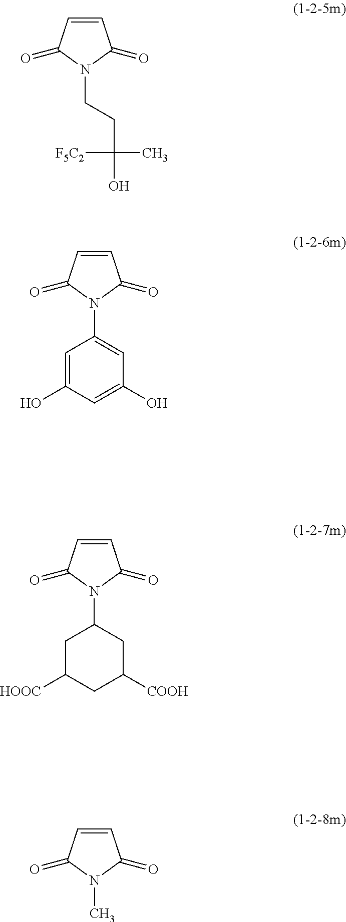

Among them, the compounds (1-1-1m) to (1-1-3m), (1-2-1m), and (1-2-2m) are preferable.

Examples of structural units other than the structural unit (I) include a structural unit containing at least one selected from the group consisting of (ii) an alkali-soluble group, (iii) an alkali-dissociable group, and (iv) an acid-dissociable group (hereinafter, also referred to as a “structural unit (II)”).

When the polymer [A] has the structural unit (II), the composition for forming a protective film can improve the sensitivity, especially the sensitivity to EUV or an electron beam.

The alkali-dissociable group (iii) refers to a group that substitutes a hydrogen atom, such as a hydroxy group and a carboxy group, and is dissociated by the action of alkali. Since the polymer [A] has a structural unit containing the alkali-dissociable group (iii), the solubility is increased by the action of an alkaline developer. The acid-dissociable group (iv) refers to a group that substitutes a hydrogen atom, such as a hydroxy group and a carboxy group, and is dissociated by the action of acid.

Examples of the alkali-soluble group (ii) include a carboxy group, a sulfo group, a phenolic hydroxyl group, a sulfonamide group, a group having a β-diketone structure, a group having a β-ketoester structure, a group having a β-dicarboxylic acid ester structure, a group having a β-thioxoketone structure, and the group (a).

Examples of the structural unit containing the alkali-soluble group include structural units represented by formulas (ii-1) to (ii-6).

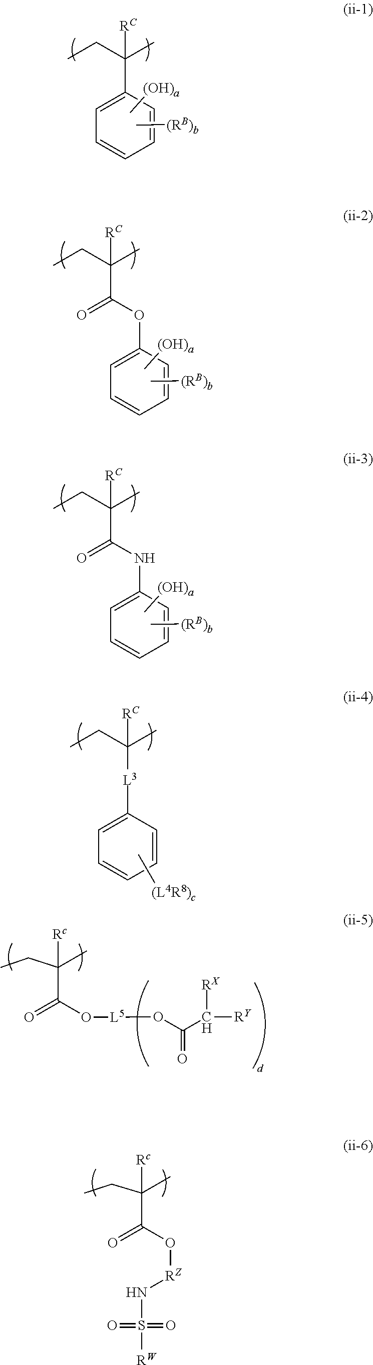

In formulas (ii-1) to (ii-6), R^{C}s are each independently a hydrogen atom, a halogen atom, or a substituted or unsubstituted alkyl group having 1 to 5 carbon atoms.

In formulas (ii-1) to (ii-3), as are each independently an integer of 1 to 3. R^{B}s are each independently an alkyl group having 1 to 5 carbon atoms. bs are each independently an integer of 0 to 4. When there are a plurality of R^{B}s, the plurality of R^{B}s may be the same as or different from each other, provided that 1≤a+b≤5 is satisfied.

In formula (ii-4), L³ and L⁴ are each independently a single bond, a methylene group, an alkylene group having 2 to 5 carbon atoms, a cycloalkylene group having 3 to 15 carbon atoms, an arylene group having 6 to 20 carbon atoms, or a divalent group obtained by combining these groups with at least one selected from the group consisting of —O— and —CO—. R⁸ is a hydrogen atom, a hydroxy group, a carboxy group, a monovalent chain hydrocarbon group having 1 to 5 carbon atoms, an alkoxy group having 1 to 5 carbon atoms, an alkoxycarbonyl group having 2 to 5 carbon atoms, or the group (a). c is an integer of 1 to 5. When there are a plurality of L⁴s and a plurality of R⁸s, the plurality of L⁴s and the plurality of R⁸s may be the same as or different from each other, provided that at least one of R⁸s is the group (a).

In formula (ii-5), R^{X} is a hydrogen atom, a halogen atom, a nitro group, an alkyl group, a monovalent alicyclic hydrocarbon group, an alkoxy group, an acyl group, an aralkyl group, or an aryl group.

Some or all of the hydrogen atoms of the alkyl group, alicyclic hydrocarbon group, alkoxy group, acyl group, aralkyl group, and aryl group may be substituted. R^{Y} is —C(═O)—R^{a} or —S(═O)₂—R^{b}. R^{a} and R^{b} are each independently a hydrogen atom, an alkyl group, a fluorinated alkyl group, a monovalent alicyclic hydrocarbon group, an alkoxy group, a cyano group, a cyanomethyl group, an aralkyl group, or an aryl group, provided that R^{a} or R^{b} and R^{X} may be bonded to each other to form a ring structure. d is an integer of 1 to 3. When there are a plurality of R^{X}s and a plurality of R^{Y}s, the plurality of R^{X}s and the plurality of R^{Y}s may be the same as or different from each other.

L⁵ is a (d+1)-valent linking group.

In formula (ii-6), R^{Z} is a divalent linking group. R^{W} is a fluorinated alkyl group having 1 to 20 carbon atoms.

Examples of the structural unit containing the alkali-soluble group (ii) include structural units represented by formulas (2-1-1) to (2-4-2).

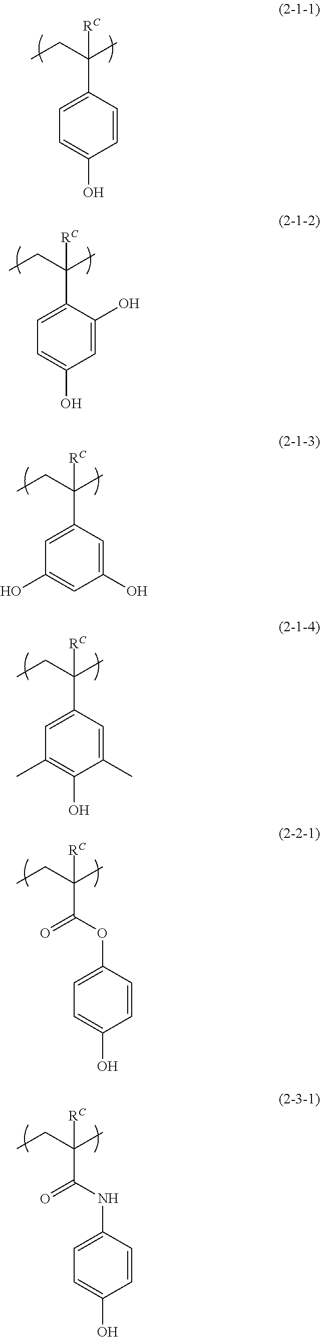

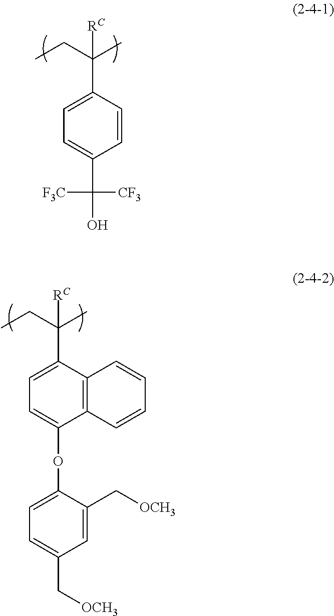

In formulas (2-1-1) to (2-4-2), R^{C} has the same meaning as in formulas (ii-1) to (ii-6).

Examples of the structural unit containing the alkali-soluble group (ii) may also include, in addition to the structural units described above, structural units represented by formulas.

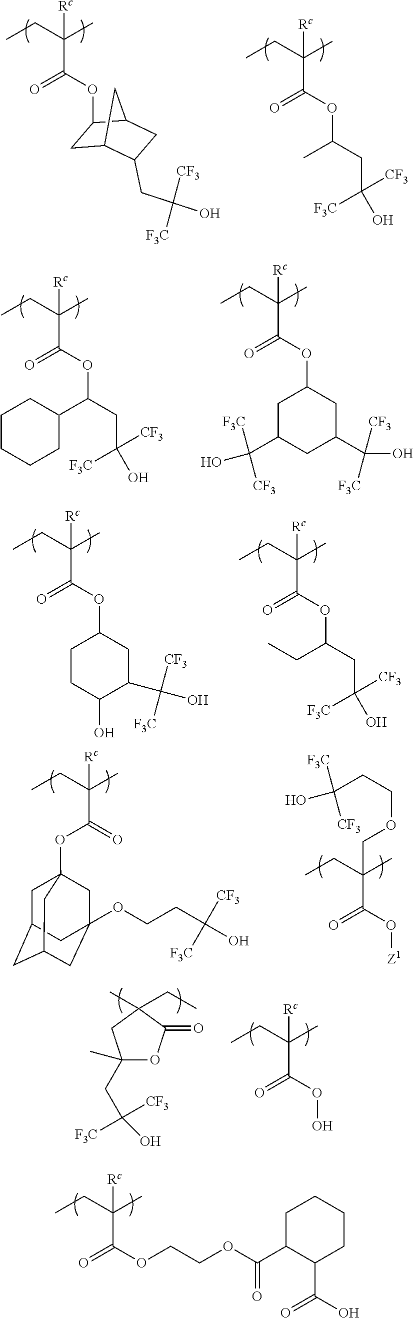

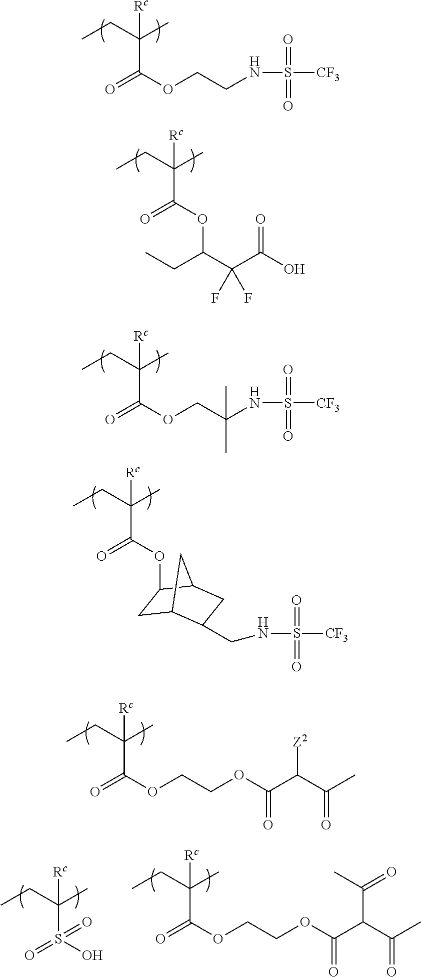

In formulas, R^{C}s are each independently a hydrogen atom, a halogen atom, or a substituted or unsubstituted alkyl group having 1 to 5 carbon atoms. Z¹ and Z² are each independently a methyl group or an ethyl group.

Examples of the structural unit containing the alkali-dissociable group (iii) include structural units represented by formulas (c2-1-1) to (c2-2-2).

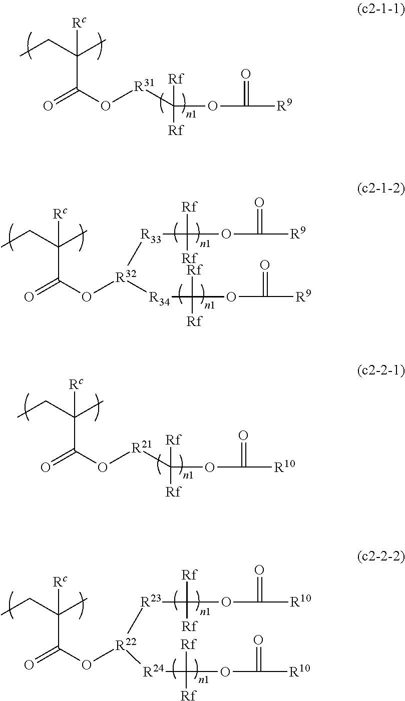

In formulas (c2-1-1) and (c2-1-2), R^{C}s are each independently a hydrogen atom or an alkyl group having 1 to 5 carbon atoms. R⁹ is a group in which —COR⁹ is an alkali-dissociable group. R⁹ is a hydrocarbon group having 1 to 20 carbon atoms or a fluorinated hydrocarbon group having 1 to 20 carbon atoms. n1s are each independently an integer of 0 to 4. Rfs are each independently a fluorine atom or a perfluoroalkyl group having 1 to 10 carbon atoms. When there are a plurality of Rfs, the plurality of Rfs may be the same as or different from each other. R³¹, R³³, and R³⁴ are each independently a single bond, a linear or branched divalent chain hydrocarbon group having 1 to 10 carbon atoms, or a divalent alicyclic hydrocarbon group having 3 to 20 carbon atoms. R³² is a trivalent linear or branched hydrocarbon group having 1 to 10 carbon atoms or a trivalent alicyclic hydrocarbon group having 4 to 20 carbon atoms, and may have an oxygen atom, a sulfur atom, a carbonyl group, or an imino group at the terminal on the R³³ or R³⁴ side.

In formulas (c2-2-1) and (c2-2-2), R^{C}s are each independently a hydrogen atom or an alkyl group having 1 to 5 carbon atoms. R¹⁰ is an alkali-dissociable group. R¹⁰ is a hydrocarbon group having 1 to 20 carbon atoms or a fluorinated hydrocarbon group having 1 to 20 carbon atoms. n1s are each independently an integer of 0 to 4. Rfs are each independently a fluorine atom or a perfluoroalkyl group having 1 to 10 carbon atoms. When there are a plurality of Rfs, the plurality of Rfs may be the same as or different from each other. R²¹, R²³, and R²⁴ are each independently a linear or branched divalent chain hydrocarbon group having 1 to 10 carbon atoms or a divalent alicyclic hydrocarbon group having 4 to 20 carbon atoms. R²² is a trivalent linear or branched hydrocarbon group having 1 to 10 carbon atoms or a trivalent alicyclic hydrocarbon group having 4 to 20 carbon atoms, and may have an oxygen atom, a sulfur atom, a carbonyl group, or an imino group at the terminal on the R²³ or R²⁴ side.

Examples of the structural unit represented by formula (c2-1-1) include structural units represented by formulas (c2-1-1a) to (c2-1-1d). Examples of the structural unit represented by formula (c2-1-2) also include structural units represented by formula (c2-1-2a) or (c2-1-2b). In formulas, R^{C} and R⁹ have the same meaning as in formulas (c2-1-1) to (c2-1-2).

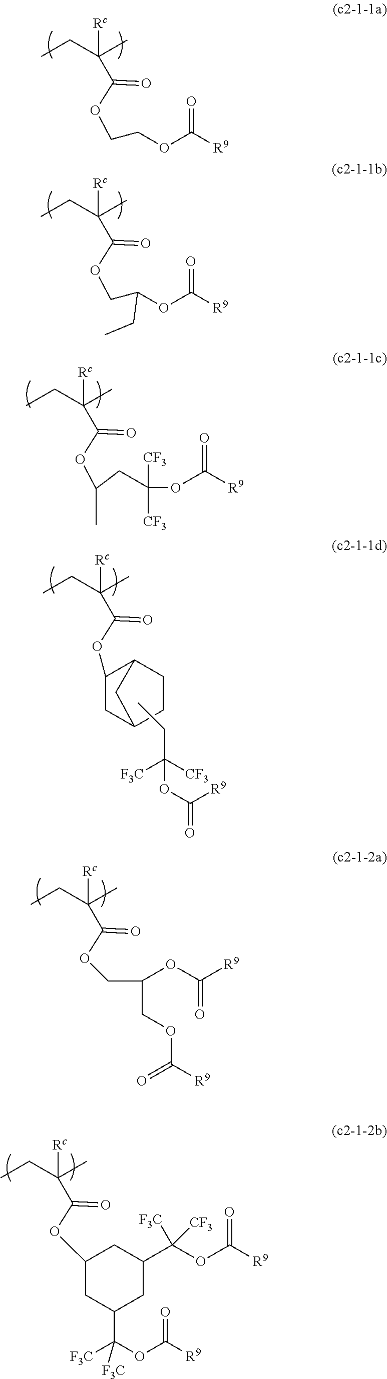

Examples of the structural unit represented by formula (c2-2-1) include structural units represented by formulas (c2-2-1a) to (c2-2-1d). In formulas, R^{C} and R¹⁰ have the same meaning as in formulas (c2-2-1) to (c2-2-2).

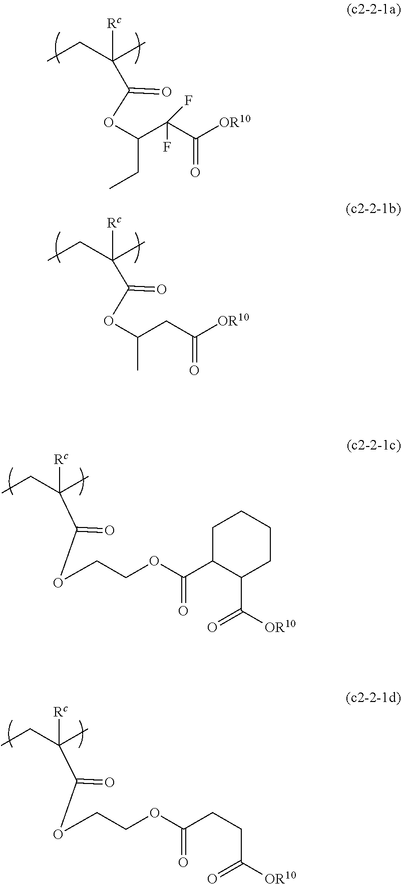

Examples of the structural unit represented by formula (c2-2-1a) include structural units represented by formulas.

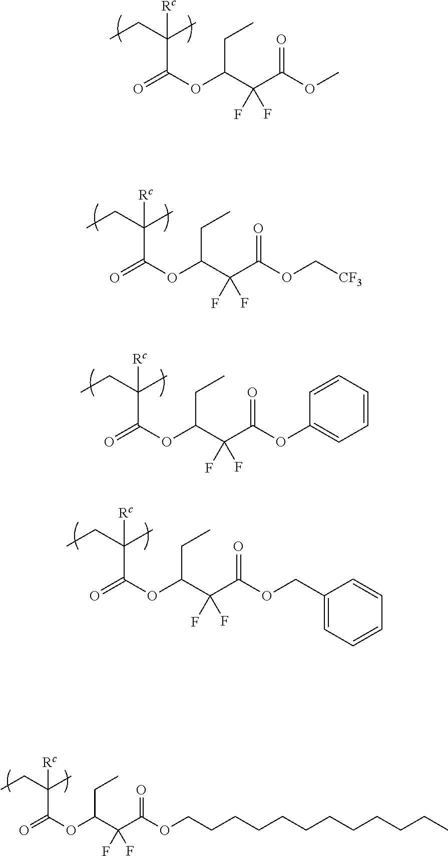

In formulas, R^{C} is a hydrogen atom or an alkyl group having 1 to 5 carbon atoms.

Examples of other structural units containing the alkali-dissociable group (iii) also include a structural unit represented by formula.

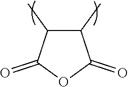

Examples of structural unit containing the acid-dissociable group (iv) include structural units represented by formulas.

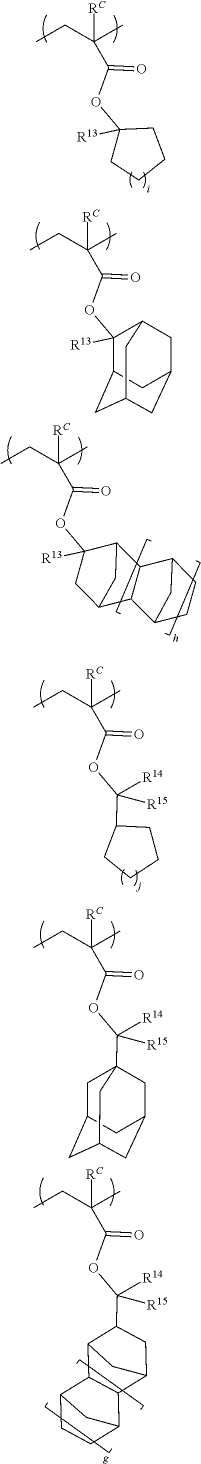

In formulas, R^{C}s are each independently a hydrogen atom, a halogen atom, or a substituted or unsubstituted alkyl group having 1 to 5 carbon atoms. R¹³, R¹⁴, and R¹⁵ are each independently a substituted or unsubstituted hydrocarbon group having 1 to 20 carbon atoms. i and j are each independently an integer of 1 to 4. h and g are each independently 0 or 1.

When the polymer [A] contains the structural unit (II), the content ratio of the structural unit (II) is preferably 2 mol % or more, more preferably 5 mol % to 40 mol %, still more preferably 8 mol % to 25 mol % with respect to all structural units constituting the polymer [A].

The polymer [A] may contain structural units represented by formulas (3-1) to (3-6) as other structural units as long as the effects of the present disclosure are not impaired.

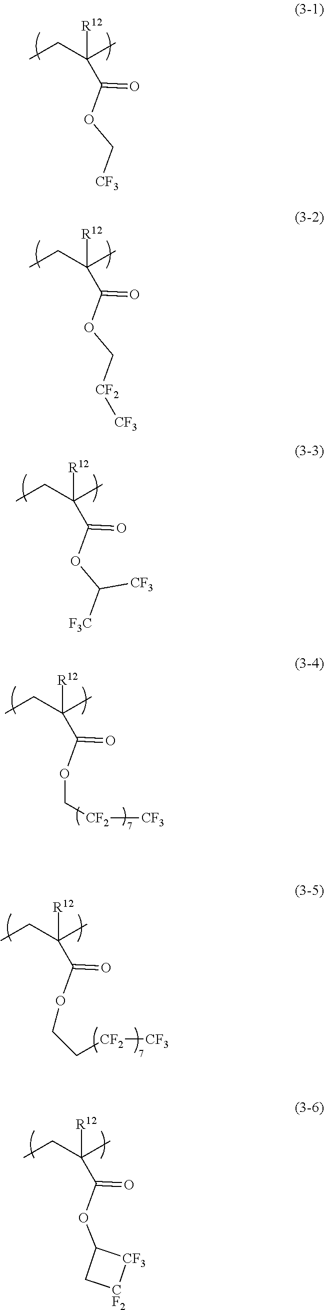

In the above formulas (3-1) to (3-6), R¹² is a hydrogen atom, a methyl group, a fluorine atom, or a trifluoromethyl group.

### [Method for Synthesizing Polymer [A]]

The polymer [A] can be produced by, for example, polymerizing a monomer corresponding to each predetermined structural unit in an appropriate solvent with the use of a radical polymerization initiator. The polymer [A] is preferably synthesized by, for example, a method in which a solution containing a monomer and a radical initiator is added dropwise to a reaction solvent or a solution containing a monomer to cause a polymerization reaction, a method in which a solution containing a monomer and a solution containing a radical initiator are separately added dropwise to a reaction solvent or a solution containing a monomer to cause a polymerization reaction, or a method in which two or more types of solutions each containing a different monomer and a solution containing a radical initiator are separately added dropwise to a reaction solvent or a solution containing a monomer to cause a polymerization reaction.

Examples of the solvent to be used in the polymerization include
alkanes such as n-pentane, n-hexane, n-heptane, n-octane, n-nonane, and n-decane; cycloalkanes such as cyclohexane, cycloheptane, cyclooctane, decalin, and norbornane;
aromatic hydrocarbons such as benzene, toluene, xylene, ethylbenzene, and cumene; halogenated hydrocarbons such as chlorobutanes, bromohexanes, dichloroethanes, hexamethylene dibromide, and chlorobenzene; saturated carboxylate esters such as ethyl acetate, n-butyl acetate, i-butyl acetate, and methyl propionate; ketones such as acetone, 2-butanone (methyl ethyl ketone), 4-methyl-2-pentanone, and 2-heptanone; ethers such as tetrahydrofuran, dimethoxyethanes, and diethoxyethanes; and alcohols such as methanol, ethanol, 1-propanol, 2-propanol, and 4-methyl-2-pentanol. These solvents may be used alone, or two or more thereof may be used in combination.

The reaction temperature in the polymerization may be appropriately determined depending on the type of the radical initiator, but is usually 40° C. to 150° C., preferably 50° C. to 120° C. The duration of reaction is usually 1 hour to 48 hours, preferably 1 hour to 24 hours.

Examples of the radical initiator to be used in the polymerization include azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), and 2,2′-azobis(2-methylpropionitrile). Two or more of these initiators may be used in combination.

The polymer obtained by the polymerization reaction is preferably collected by reprecipitation. That is, after completion of the polymerization reaction, the polymerization liquid is charged into a reprecipitation solvent to collect a target polymer as a powder. As the reprecipitation solvent, alcohols, alkanes, and the like can be used alone or as a mixture of two or more thereof. In addition to the reprecipitation method, the polymer can also be collected by removing low molecular weight components such as monomers and oligomers by liquid separation operation, column operation, ultrafiltration operation, or the like.

The weight-average molecular weight (Mw) of the polymer [A] measured by gel permeation chromatography (GPC) is preferably 1,000 to 100,000, more preferably 1,000 to 50,000, still more preferably 1,000 to 30,000. By adjusting the Mw of the polymer [A] within the above range, a protective film further excellent in ability to suppress out-of-band and outgas can be formed.

The ratio of the Mw to the number average molecular weight (Mn) of the polymer [A] (Mw/Mn) is usually 1 to 5, preferably 1 to 3. By adjusting the Mw/Mn of the polymer [A] within such a specific range, a protective film further excellent in ability to suppress out-of-band and outgas can be formed.

The Mw and the Mn in this description refer to values measured by gel permeation chromatography (GPC) using GPC columns (G2000HXL×2, G3000HXL×1, and G4000HXL×1 manufactured by Tosoh Corporation), a differential refractometer as a detector, and monodisperse polystyrene standards under analysis conditions of a flow rate of 1.0 mL/min, an elution solvent of tetrahydrofuran, a sample concentration of 1.0 mass %, a sample injection amount of 100 μL, and a column temperature of 40° C.

### [Organic Solvent [B]]

The organic solvent [B] is not particularly limited as long as the organic solvent [B] can dissolve the polymer [A] and optional components, and hardly elutes the resist film component, but examples thereof include alcohol-based solvents, ether-based solvents, ketone-based organic solvents, amide-based solvents, ester-based solvents, and hydrocarbon-based solvents.

Examples of the alcohol-based solvent include monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, 4-methyl-2 pentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, diacetone alcohol; polyhydric alcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and
polyhydric alcohol partial ether-based solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethyl butyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether. Among them, 4-methyl-2-pentanol is preferable.

Examples of the ether-based solvent include dipropyl ether, diisopropyl ether, butyl methyl ether, butyl ethyl ether, butyl propyl ether, dibutyl ether, diisobutyl ether, tert-butyl-methyl ether, tert-butyl ethyl ether, tert-butyl propyl ether, di-tert-butyl ether, dipentyl ether, diisoamyl ether, cyclopentyl methyl ether, cyclohexyl methyl ether, cyclopentyl ethyl ether, cyclohexyl ethyl ether, cyclopentyl propyl ether, cyclopentyl-2-propyl ether, cyclohexyl propyl ether, cyclohexyl-2-propyl ether, cyclopentyl butyl ether, cyclopentyl-tert-butyl ether, cyclohexyl butyl ether, cyclohexyl-tert-butyl ether, anisole, diethyl ether, and diphenyl ether. Examples of the cyclic ether may include tetrahydrofuran and dioxane. Among them, diisoamyl ether is preferable.

Examples of the ketone-based solvent include ketone-based solvents such as acetone, methyl ethyl ketone, methyl-n-propyl ketone, methyl-n-butyl ketone, diethyl ketone, methyl-iso-butyl ketone, methyl-n-amyl ketone, ethyl-n-butyl ketone, methyl-n-hexyl ketone, di-iso-butyl ketone, trimethylnonanone, cyclopentanone, cyclohexanone, cycloheptanone, cyclooctanone, methylcyclohexanone, 2,4-pentanedione, acetonylacetone, and acetophenone.

Examples of the amide-based solvent include N,N′-dimethylimidazolidinone, N-methylformamide, N,N-dimethylformamide, N,N-diethylformamide, acetamide, N-methylacetamide, N,N-dimethylacetamide, N-methylpropionamide, and N-methylpyrrolidone.

Examples of the ester-based solvent include diethyl carbonate, propylene carbonate, methyl acetate, ethyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonylacetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of the hydrocarbon-based solvent include aliphatic hydrocarbon-based solvents such as n-pentane, iso-pentane, n-hexane, iso-hexane, n-heptane, iso-heptane, 2,2,4-trimethylpentane, n-octane, iso-octane, cyclohexane, and methylcyclohexane; and
aromatic hydrocarbon-based solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene, and n-amylnaphthalene.

Among them, the organic solvent [B] preferably contains at least one solvent selected from the group consisting of an ether-based solvent and an alcohol-based solvent, more preferably contains an ether-based solvent and an alcohol-based solvent, from the viewpoint that elution of components from a resist film, which causes outgas in subsequent exposure, is unlikely to occur when the composition for forming a protective film is applied. As the ether-based solvent, an ether-based solvent having 6 to 14 carbon atoms is preferable, an ether-based solvent having 8 to 12 carbon atoms is more preferable, a dialiphatic ether-based solvent having 8 to 12 carbon atoms is still more preferable, and diisoamyl ether is particularly preferable. As the alcohol-based solvent, an alcohol-based solvent having 3 to 9 carbon atoms is preferable, an alcohol-based solvent having 5 to 7 carbon atoms is more preferable, a monoalcohol-based solvent having 5 to 7 carbon atoms is still more preferable, and 4-methyl-2-pentanol is particularly preferable.

It is also preferable that the organic solvent [B] contain an ether-based solvent, and the content of the ether-based solvent be 10 mass % or more, more preferably 20 mass % or more, still more preferably 50 mass % or more.

These organic solvents may be used alone, or two or more thereof may be used in combination.

### [Optional Component]

The composition for forming a protective film may contain an optional component in addition to the polymer [A] and the organic solvent [B] as long as the effects of the present disclosure are not impaired. Examples of the optional component include an acid diffusion controlling agent and an acid generator. As the acid diffusion controlling agent and the acid generator, known compounds can be used.

The acid diffusion controlling agent has an effect of suppressing diffusion of an acid generated in a resist film to an unexposed portion via a protective film, or suppressing diffusion of the acid diffusion controlling agent in a resist film into a protective film due to a concentration gradient.

The acid generator has an effect of compensating for the shortage of an acid in a resist film, which shortage is caused by diffusion of an acid that is to contribute to the deprotection reaction in a resist film into a protective film.

### [Method for Preparing Composition for Forming Protective Film]

The composition for forming a protective film is prepared, for example, by mixing the polymer [A] and an optional component in a predetermined ratio in the organic solvent [B]. The composition for forming a protective film can be prepared and used in a state of being dissolved or dispersed in the appropriate organic solvent [B]. The obtained mixed liquid may be filtered through a membrane filter or the like having a pore size of 0.4 μm or less, if necessary.

Using the composition for forming a protective film having the above configuration in the method for forming a resist pattern according to the present embodiment can further improve the nano-edge roughness by suppressing the acid diffusion from a metal-containing resist film to a protective film at the time of PEB or the like due to the fact that the protective film absorbs the out-of-band and/or the glass transition temperature is relatively high while more sufficiently satisfying the sensitivity of the metal-containing resist, and also can further suppress generation of outgas from the metal-containing resist film by relatively increasing the glass transition temperature of a protective film.

### EXAMPLES

Hereinafter, the present invention will be specifically described with reference to Examples, but the present invention is not limited to these Examples. A method for measuring physical property values in this Example is shown below.

### [Mw and Mn of Polymer]

The Mw and Mn of a polymer were measured according to the procedure described above.

### [¹³C-NMR Analysis]

¹³C-NMR analysis for determining the content ratio of the structural unit of the polymer was performed using a nuclear magnetic resonance apparatus (JNM-ECX400, manufactured by JEOL Ltd.), CDCl₃ as a measurement solvent, and tetramethylsilane (TMS) as an internal standard.

### <Synthesis of Polymer>

Monomers used for synthesis of the polymer [A] are shown below.

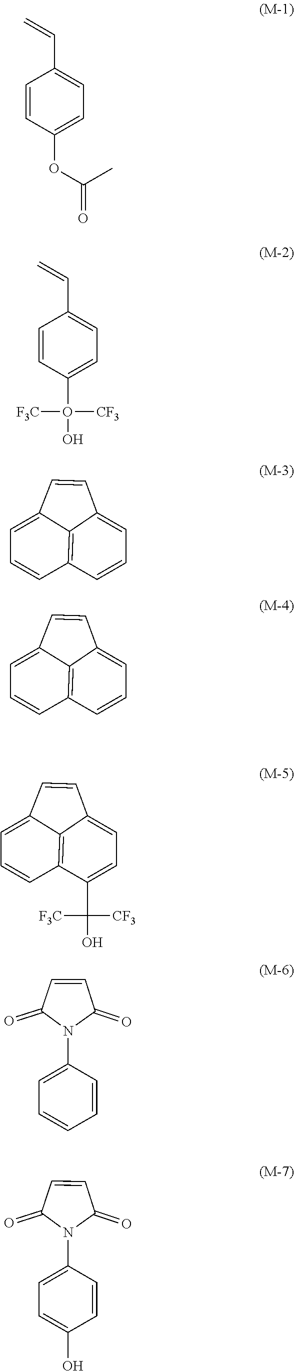

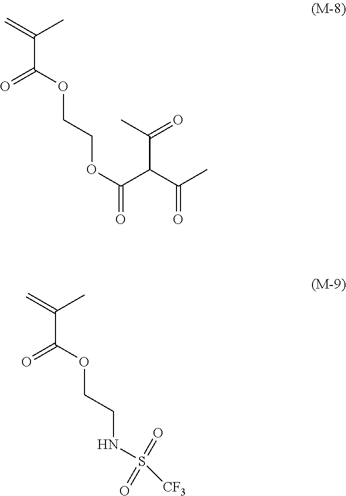

Compounds (M-3) to (M-7) give the structural unit (I), and respective compounds (M-1), (M-2), (M-8) and (M-9) give other structural units.

### Synthesis Example 1

Polymerization was performed by dissolving 64 g (50 mol %) of the compound (M-2), 36 g (50 mol %) of the compound (M-3), and 7.7 g of AIBN in 200 g of methyl ethyl ketone, and then maintaining the reaction temperature at 78° C. for 6 hours in a nitrogen atmosphere. After the polymerization, methyl ethyl ketone was distilled off under reduced pressure, and the obtained polymer was dissolved in 100 g of methyl ethyl ketone. Subsequently, the obtained solution was added dropwise to 2,000 g of n-hexane to solidify and purify the polymer. Next, this polymer was washed with 300 g of hexane twice, and the obtained white powder was filtered and dried at 50° C. under reduced pressure overnight to yield a polymer (A-1). The polymer (A-1) had an Mw of 6,000 and an Mw/Mn of 1.8. As a result of ¹³C-NMR analysis, the content ratio of the structural units derived from the compound (M-2) and the compound (M-3) was 50 mol % and 50 mol %, respectively.

### Synthesis Example 2

Polymerization was performed by dissolving 62 g (50 mol %) of the compound (M-2), 38 g (50 mol %) of the compound (M-4), and 7.5 g of AIBN in 200 g of methyl ethyl ketone, and then maintaining the reaction temperature at 78° C. for 6 hours in a nitrogen atmosphere. After the polymerization, methyl ethyl ketone was distilled off under reduced pressure, and the obtained polymer was dissolved in 100 g of methyl ethyl ketone. Subsequently, the obtained solution was added dropwise to 2,000 g of n-hexane to solidify and purify the polymer. Next, this polymer was washed with 300 g of hexane twice, and the obtained white powder was filtered and dried at 50° C. under reduced pressure overnight to yield a polymer (A-2). The polymer (A-2) had an Mw of 6,500 and an Mw/Mn of 1.9. As a result of ¹³C-NMR analysis, the content ratio of the structural units derived from the compound (M-2) and the compound (M-4) was 50 mol % and 50 mol %, respectively.

### Synthesis Example 3

Polymerization was performed by dissolving 34 g (50 mol %) of the compound (M-1), 66 g (50 mol %) of the compound (M-5), 6.8 g of AIBN, and 2.6 g of t-dodecyl mercaptan in 200 g of propylene glycol monomethyl ether, and then maintaining the reaction temperature at 70° C. for 6 hours in a nitrogen atmosphere. After the polymerization, propylene glycol monomethyl ether was distilled off under reduced pressure, and the obtained polymer was dissolved in 100 g of propylene glycol monomethyl ether. Subsequently, the obtained solution was added dropwise to 2,000 g of n-hexane to solidify and purify the polymer. Next, hydrolysis reaction was performed by adding to this polymer 150 g of propylene glycol monomethyl ether again, and then further adding 150 g of methanol, 30 g of triethylamine and 6 g of water, followed by refluxing at a boiling point for 8 hours. After confirming by infrared spectroscopy that deacetylation had proceeded quantitatively to produce a structural unit derived from p-hydroxystyrene, the solvent and triethylamine were distilled off under reduced pressure. The obtained polymer was dissolved in 150 g of acetone, then the obtained solution was added dropwise to 2,000 g of water for solidification, and the generated white powder was filtered and dried at 50° C. under reduced pressure overnight to yield a polymer (A-3). The polymer (A-3) had an Mw of 10,000 and an Mw/Mn of 2.1. As a result of ¹³C-NMR analysis, the content ratio of the structural unit derived from p-hydroxystyrene and the structural unit derived from the compound (M-5) was 50 mol % and 50 mol %, respectively.

### Synthesis Example 4

Polymerization was performed by dissolving 48 g (50 mol %) of the compound (M-2), 52 g (50 mol %) of the compound (M-6), and 9.8 g of AIBN in 200 g of methyl ethyl ketone, and then maintaining the reaction temperature at 78° C. for 6 hours in a nitrogen atmosphere. After the polymerization, methyl ethyl ketone was distilled off under reduced pressure, and the obtained polymer was dissolved in 100 g of methyl ethyl ketone. Subsequently, the obtained solution was added dropwise to 2,000 g of n-hexane to solidify and purify the polymer. Next, this polymer was washed with 300 g of hexane twice, and the obtained white powder was filtered and dried at 50° C. under reduced pressure overnight to yield a polymer (A-4). The polymer (A-4) had an Mw of 9,000 and an Mw/Mn of 2.2. As a result of ¹³C-NMR analysis, the content ratio of the structural units derived from the compound (M-2) and the compound (M-6) was 50 mol % and 50 mol %, respectively.

### Synthesis Example 5

Polymerization was performed by dissolving 46 g (50 mol %) of the compound (M-1), 54 g (50 mol %) of the compound (M-7), 9.4 g of AIBN, and 3.5 g of t-dodecyl mercaptan in 200 g of propylene glycol monomethyl ether, and then maintaining the reaction temperature at 70° C. for 6 hours in a nitrogen atmosphere. After the polymerization, propylene glycol monomethyl ether was distilled off under reduced pressure, and the obtained polymer was dissolved in 100 g of propylene glycol monomethyl ether. Subsequently, the obtained solution was added dropwise to 2,000 g of n-hexane to solidify and purify the polymer. Next, hydrolysis reaction was performed by adding to this polymer 150 g of propylene glycol monomethyl ether again, and then further adding 150 g of methanol, 36 g of triethylamine and 6 g of water, followed by refluxing at a boiling point for 8 hours. After confirming by infrared spectroscopy that deacetylation had proceeded quantitatively to produce a structural unit derived from p-hydroxystyrene, the solvent and triethylamine were distilled off under reduced pressure. The obtained polymer was dissolved in 150 g of acetone, then the obtained solution was added dropwise to 2,000 g of water for solidification, and the generated white powder was filtered and dried at 50° C. under reduced pressure overnight to yield a polymer (A-5). The polymer (A-5) had an Mw of 10,000 and an Mw/Mn of 2.0. As a result of ¹³C-NMR analysis, the content ratio of the structural unit derived from p-hydroxystyrene and the structural unit derived from the compound (M-7) was 50 mol % and 50 mol %, respectively.

### Synthesis Example 6

Polymerization was performed by dissolving 48 g (30 mol %) of the compound (M-2), 52 g (50 mol %) of the compound (M-5), 52 g (20 mol %) of the compound (M-8), and 9.8 g of AIBN in 200 g of methyl ethyl ketone, and then maintaining the reaction temperature at 78° C. for 6 hours in a nitrogen atmosphere. After the polymerization, methyl ethyl ketone was distilled off under reduced pressure, and the obtained polymer was dissolved in 100 g of methyl ethyl ketone. Subsequently, the obtained solution was added dropwise to 2,000 g of n-hexane to solidify and purify the polymer. Next, this polymer was washed with 300 g of hexane twice, and the obtained white powder was filtered and dried at 50° C. under reduced pressure overnight to yield a polymer (A-6). The polymer (A-6) had an Mw of 10,000 and an Mw/Mn of 2.1. As a result of ¹³C-NMR analysis, the content ratio of the structural units derived from the compound (M-2), the compound (M-5), and the compound (M-8) was 30 mol %, 50 mol %, and 20 mol %, respectively.

### Synthesis Example 7

Polymerization was performed by dissolving 48 g (40 mol %) of the compound (M-2), 52 g (50 mol %) of the compound (M-6), 52 g (10 mol %) of the compound (M-9), and 8.8 g of AIBN in 200 g of methyl ethyl ketone, and then maintaining the reaction temperature at 78° C. for 6 hours in a nitrogen atmosphere. After the polymerization, methyl ethyl ketone was distilled off under reduced pressure, and the obtained polymer was dissolved in 100 g of methyl ethyl ketone. Subsequently, the obtained solution was added dropwise to 2,000 g of n-hexane to solidify and purify the polymer. Next, this polymer was washed with 300 g of hexane twice, and the obtained white powder was filtered and dried at 50° C. under reduced pressure overnight to yield a polymer (A-7). The polymer (A-7) had an Mw of 7,000 and an Mw/Mn of 2.0. As a result of ¹³C-NMR analysis, the content ratio of the structural units derived from the compound (M-2), the compound (M-6), and the compound (M-9) was 40 mol %, 50 mol %, and 10 mol %, respectively.

### <Preparation of Composition for Forming Protective Film>

The organic solvents [B] used for preparation of the composition for forming a protective film are shown below.

### [Organic Solvent [B]]

B-1: 4-methyl-2-pentanol
B-2: diisoamyl ether

### Preparation Example 1

A composition for forming a protective film (T-1) was prepared by mixing 100 parts by mass of the polymer (A-1) synthesized in Synthesis Example 1 and 10,000 parts by mass of the organic solvent (B-2), and filtering the obtained mixed liquid using a membrane filter having a pore size of 0.20 μm.

### Preparation Examples 2 to 7

Compositions for forming protective films (T-2) to (T-7) were prepared in the same manner as in Preparation Example 1 except that respective components whose types and blending amounts were shown in Table 1 were used.

TABLE 1

| | Composition | Polymer | | Organic solvent | |
|---|---|---|---|---|---|
| | for | | Blending | | Blending |
| | forming | | amount | | amount |
| | protective | | (parts by | | (parts by |
| | film | Type | mass ) | Type | mass ) |
| Preparation | T-1 | A-1 | 100 | B-2 | 10000 |
| Example 1 | | | | | |
| Preparation | T-2 | A-2 | 100 | B-2 | 10000 |
| Example 2 | | | | | |
| Preparation | T-3 | A-3 | 100 | B-2 | 10000 |
| Example 3 | | | | | |
| Preparation | T-4 | A-4 | 100 | B-1/B-2 | 500/9500 |
| Example 4 | | | | | |
| Preparation | T-5 | A-5 | 100 | B-1/B-2 | 9000/1000 |
| Example 5 | | | | | |
| Preparation | T-6 | A-6 | 100 | B-1/B-2 | 300/9700 |
| Example 6 | | | | | |
| Preparation | T-7 | A-7 | 100 | B-1/B-2 | 300/9700 |
| Example 7 | | | | | |

### <Formation of Metal-Containing Resist Film 1>

A metal-containing resist film (R-1) having a film thickness of 5 nm was formed at 350° C. at a methyltin trichloride flow rate of 200 ccm and a CO₂ flow rate of 1000 sccm on the surface of a 12 inch silicon wafer by a CVD apparatus.

### <Formation of Metal-Containing Resist Film 2>

A substrate (S) was prepared by forming a silicon dioxide film having a film thickness of 20 nm on a 12 inch silicon wafer. On the surface of the substrate (S) prepared as described above, a metal-containing resist film having a film thickness of 2 nm (R-2) was formed by depositing Sn(CH₃)₄ using a CVD device, under a pressure maintained at about 1 Torr at 20° C.

### Examples 1 to 7 and Comparative Examples 1 to 2

### <Formation of Resist Pattern>

The metal-containing resist film prepared as above was spin-coated with the composition for forming a protective film shown in Table 1, and PB was performed at 110° C. for 60 seconds to form a protective film having a film thickness of 30 nm. In the comparative examples, the protective film was not formed. Next, the film was irradiated with an extreme ultraviolet ray using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). Thereafter, PEB was performed at 100° C. for 60 seconds, and development was then performed at 23° C. for 1 minute by a paddle method using a 2.38 mass % aqueous tetramethylammonium hydroxide solution. After water washing was performed, development was performed for 1 minute by a paddle method using ethanol/water (volume ratio 70/30) heated to 40° C., and drying was then performed to form a resist pattern.

### Evaluation

The formed resist pattern was evaluated as described below.

### [Sensitivity]

An exposure amount for forming a line-and-space pattern (1L1S) including line portions each having a line width of 16 nm and space portions each having an interval of 16 nm formed by the adjacent line portions at a line width of 1:1 was defined as an optimum exposure amount, and this optimum exposure amount was defined as sensitivity (mJ/cm²).

### [Nano-Edge Roughness]

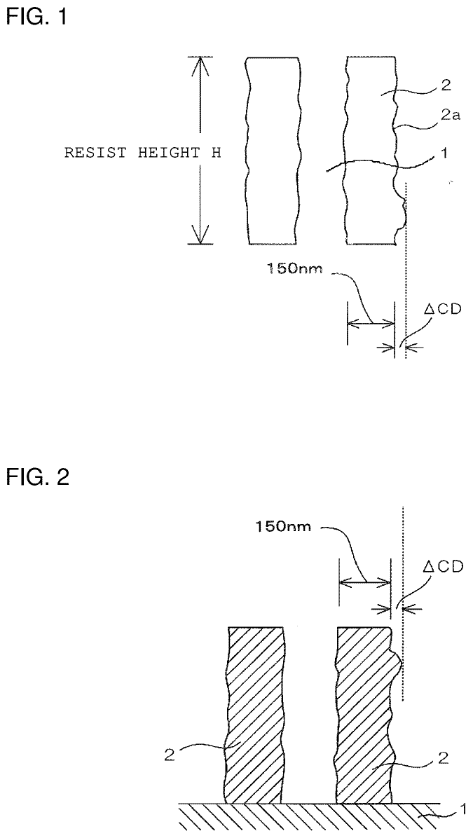

The line pattern of the line-and-space pattern (1L1S) was observed using a scanning electron microscope for semiconductor (High-resolution FEB measuring device 5-9220, manufactured by Hitachi, Ltd.). Arbitrary 50 points of the pattern were observed, and for the observed shape, as shown in FIGS. 1 and 2, the difference “ΔCD” between the designed line width of 16 nm and the line width at a point where the unevenness generated along the lateral side surface 2a of the line portion 2 of the resist film (resist height H: 5 nm or 2 nm) formed on the silicon wafer 1 was the most remarkable was measured by CD-SEM (5-9220, manufactured by Hitachi High-Technologies Corporation) and defined as nano-edge roughness (nm). The nano-edge roughness (nm) can be evaluated as “AA (extremely good)” when the nano-edge roughness (nm) is 2.8 (nm) or less, “A (good)” when the nano-edge roughness (nm) is more than 2.8 (nm) and 3.4 (nm) or less, or “B (poor)” when the nano-edge roughness (nm) is more than 3.4 (nm). The unevenness is shown in FIGS. 1 and 2 with exaggeration than actual one.

### [Outgas]

The metal-containing resist film prepared as above was spin-coated with the composition for forming a protective film shown in Table 1, and PB was performed at 110° C. for 60 seconds to form a protective film having a film thickness of 30 nm. In the comparative examples, the protective film was not formed. Next, using a KrF projection exposure apparatus (S203B, manufactured by Nikon Corporation), the entire surface of the metal-containing resist film on which the protective film was laminated was exposed without passing through a mask pattern at an exposure amount of 15 mJ/cm² under the conventional optical conditions of NA: 0.68 and Sigma: 0.75. The exposed metal-containing resist film was subjected to outgas analysis using a thermal desorption gas chromatography mass spectrometer (SWA-256, manufactured by GL Sciences Inc.).

The outgas analysis was performed by desorbing an organic substance from the surface of the metal-containing resist film at 25° C. for 60 minutes, once collecting the desorbed outgas component in a collection column, then heating the collection column at 200° C. to desorb the organic substance again from the collection column, cooling the organic substance using liquid nitrogen in a thermal desorption cold trap injector to cause volume contraction, and then rapidly heating the organic substance to 230° C. to introduce the collected gas component at once into gas chromatography (JNS-GCMATE GCMS SYSTEM, manufactured by JEOL Ltd.).

The value of the amount of outgas in the outgas analysis is a relative value when the amount of outgas determined by analysis for each of the metal-containing resist films in Comparative Examples 1 and 2 in which the protective film was not formed is 100.

TABLE 2

| | Composition | Metal- | | Nano- | |
|---|---|---|---|---|---|
| | for forming | containing | | edge | Amount |
| | protective | resist | Sensitivity | roughness | of |
| | film | film | (mJ/cm²) | (nm) | outgas |
| Example 1 | T-1 | R-1 | 40 | 2.6 | 60 |
| Example 2 | T-2 | R-1 | 39 | 2.7 | 50 |
| Example 3 | T-3 | R-1 | 38 | 2.7 | 40 |
| Example 4 | T-4 | R-2 | 41 | 2.7 | 50 |
| Example 5 | T-5 | R-2 | 42 | 2.6 | 30 |
| Example 6 | T-6 | R-2 | 41 | 2.6 | 20 |
| Example 7 | T-7 | R-2 | 43 | 2.7 | 30 |
| Comparative | — | R-1 | 45 | 3.3 | 100 |
| Example 1 | | | | | |
| Comparative | — | R-2 | 46 | 3.3 | 100 |
| Example 2 | | | | | |

From these results, it can be seen that the method for forming a resist pattern of Examples greatly improves the nano-edge roughness while maintaining the sensitivity, and also the generation of outgas is remarkably suppressed as compared with Comparative Examples.

According to the present disclosure, it is possible to provide a novel method for forming a resist pattern capable of improving the nano-edge roughness, sufficiently satisfying the sensitivity, and also reducing outgas. Accordingly, the method for forming a resist pattern according to the present disclosure can suitably be used for resist pattern formation in a lithography step for various electronic devices such as semiconductor devices and liquid crystal devices.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for forming a resist pattern, comprising:
forming a metal-containing resist film directly or indirectly on a substrate;
laminating a protective film on the metal-containing resist film by applying a composition for forming a protective film;
exposing to light the metal-containing resist film on which the protective film is laminated; and
removing a portion of the exposed metal-containing resist film to form a pattern.

2. The method according to claim 1, wherein exposing comprises exposing to an extreme ultraviolet ray the metal-containing resist film on which the protective film is laminated.

3. The method according to claim 1, wherein the composition for forming a protective film comprises a polymer comprising at least one structural unit selected from the group consisting of a structural unit represented by formula (1), a structural unit represented by formula (2), a structural unit represented by formula (3), and a structural unit represented by formula (4): 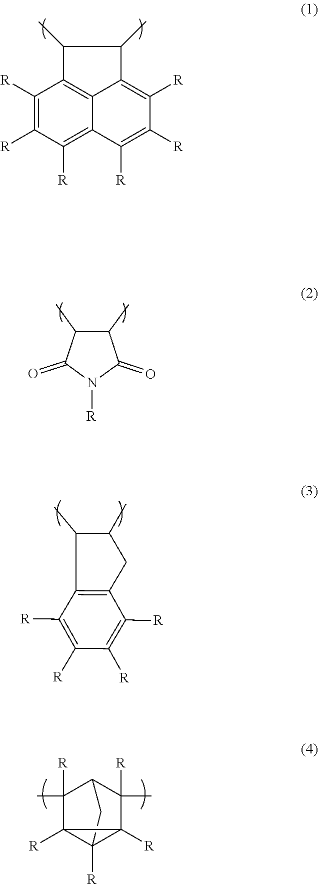
wherein in formulas (1) to (4), Rs are each independently a hydrogen atom, a halogen atom, a hydroxy group, or a monovalent organic group having 1 to 20 carbon atoms.

4. The method according to claim 1, wherein removing the portion of the exposed metal-containing resist film comprises dissolving an exposed portion of the exposed metal-containing resist film with a developer to form a pattern.

5. The method according to claim 4, wherein forming the metal-containing resist film comprises depositing a metal compound to form the metal-containing resist film.

6. The method according to claim 5, wherein depositing the metal compound is performed by CVD or ALD.

7. The method according to claim 4, wherein the metal-containing resist film comprises an organotin oxide.

8. The method according to claim 5, wherein the metal compound comprises at least one selected from the group consisting of a haloalkyl Sn, an alkoxyalkyl Sn, and an amidoalkyl Sn.

9. The method according to claim 5, wherein the metal compound comprises at least one selected from the group consisting of trimethyltin chloride, dimethyltin dichloride, methyltin trichloride, tris(dimethylamino)methyltin(IV), and (dimethylamino)trimethyltin(IV).

10. The method according to claim 4, wherein the developer comprises alcohol.

11. The method according to claim 4, wherein a temperature of the developer is 40° C. or higher.

12. The method according to claim 1, wherein removing the portion of the exposed metal-containing resist film comprises removing an unexposed portion of the exposed metal-containing resist film by heating to form the pattern.

13. The method according to claim 12, wherein a metal atom contained in the metal-containing resist film belongs to groups 3 to 16 of a periodic table.

14. The method according to claim 12, wherein a metal atom contained in the metal-containing resist film is at least one selected from the group consisting of Sn and Hf.

15. The method according to claim 12, wherein forming the metal-containing resist film comprises depositing a metal compound to form the metal-containing resist film.

16. The method according to claim 15, wherein the metal compound is represented by formula (1):
M(X)₄ (1)
wherein in formula (1), M is Sn or Hf; and Xs are each independently a halogen atom or an alkyl group.

17. The method according to claim 15, wherein the metal compound is at least one selected from the group consisting of Sn(CH₃)₄, Sn(Br)₄, and HfCl₄.

18. The method according to claim 1, wherein an unexposed portion of the exposed metal-containing resist film is volatilized to form the pattern.
